(19) United States
(12) Patent Application Publication
(10) Pub. No.: US 2021/0043695 A1
(43) Pub. Date: Feb. 11, 2021

(54) DISPLAY PANEL, DISPLAY DEVICE AND DRIVING METHOD THEREOF

(71) Applicant: BOE TECHNOLOGY GROUP CO., LTD., Beijing (CN)

(72) Inventors: Bo WANG, Beijing (CN); Ge ZHANG, Beijing (CN); Fuqiang LI, Beijing (CN)

(21) Appl. No.: 16/822,244

(22) Filed: Mar. 18, 2020

(30) Foreign Application Priority Data
Aug. 5, 2019 (CN) 201910716244.2

(51) Int. Cl. H01L 27/32

(52) U.S. Cl. CPC H01L 27/3218; H01L 27/3213; H01L 27/3234

(57) ABSTRACT

The present disclosure relates to a display panel, a display device, and a driving method for the display device, and relates to the field of display technology. The display panel includes a display area having a plurality of pixels, each of the pixels including a plurality of sub-pixels; and the display area is at least divided into a first area and a second area, the pixel density of the first area is smaller than the pixel density of the second area, and the number of sub-pixels in each of the pixels of the first area is larger than the number of sub-pixels in each of the pixels of the second area. The display panel according to the present disclosure may achieve a full-screen display, and avoid a hole or holes for mounting the camera module on the display panel.

### CROSS-REFERENCE TO RELATED APPLICATIONS

This application is based upon and claims priority to Chinese Patent Application No. 201910716244.2, filed Aug. 5, 2019, the entire contents of which are incorporated herein by reference.

### TECHNICAL FIELD

The present disclosure relates to the field of display technology, and more particularly, to a display panel, a display device, and a driving method for the display device.

### BACKGROUND

For a terminal device, for example, a mobile phone, a tablet, and the like, a front camera is usually required to be installed, so as to allow users to capture images. Currently, the front camera is generally installed within a bezel of the display panel to avoid blocking a display area, but this may make the bezel wider; or, there may be a hole or holes in the display panel to accommodate the camera and achieve a narrow bezel. However, the image cannot be displayed in a region of the display panel with the hole or holes, so that the area of the display area may be reduced and full-screen display may not be achieved.

It should be noted that the information disclosed in the background section above is only used to enhance the understanding of the background of the present disclosure, and therefore may include information that does not constitute the prior art known to those of ordinary skill in the art.

### SUMMARY

The present disclosure is providing a display panel, a display device, and a driving method for the display device.

According to an aspect of the present disclosure, there is provided a display panel, including a display area having a plurality of pixels, each of the pixels including a plurality of sub-pixels;

wherein the display area is at least divided into a first area and a second area, and a pixel density of the first area is smaller than a pixel density of the second area, and a number of sub-pixels in each of the pixels of the first area is larger than the number of sub-pixels in each of the pixels of the second area.

According to an aspect of the present disclosure, there is provided a display device, including:

the display panel according to any one of the above items; and

a camera module disposed on a backlight side of the display panel and directly facing the first area.

According to an aspect of the present disclosure, there is provided a method for driving the display device according to any one of the above aspects, wherein the driving method includes:

during a display period, controlling the first area and the second area to perform image display, and turning off the camera module; and

during a shooting period, turning off the first area, controlling the second area to perform image display, and controlling the camera module to shoot.

It is to be understood that both the foregoing general description and the following detailed description are exemplary and explanatory only and are not restrictive of the present disclosure.

### BRIEF DESCRIPTION OF THE DRAWINGS

The drawings herein, which are incorporated in and constitute a part of this specification, illustrate embodiments consistent with the present disclosure, and serve to explain the principles of the present disclosure together with the description. Obviously, the drawings in the following description are just some embodiments of the present disclosure. For those of ordinary skill in the art, other drawings may be obtained based on these drawings without creative efforts.

FIG. 1 is a schematic top view of an embodiment of a display device of the present disclosure.

FIG. 2 is a schematic side view of an embodiment of a display device of the present disclosure.

FIG. 3 is a partial schematic diagram of a first area in an embodiment of a display panel of the present disclosure.

FIG. 4 is a partial schematic diagram of a second area in an embodiment of a display panel of the present disclosure.

FIG. 5 is a flow chart illustrating an embodiment of a method for driving a display panel of the present disclosure.

### DETAILED DESCRIPTION

Example embodiments will now be described more fully with reference to the accompanying drawings. However, the example embodiments can be implemented in various forms and should not be construed as limited to the embodiments set forth herein; rather, these embodiments are provided so that this disclosure will be thorough and complete, and will fully convey the concept of the example embodiments to those skilled in the art. The same reference numerals in the drawings denote the same or similar structures, and thus their detailed descriptions will be omitted. In addition, the drawings are merely schematic illustrations of the present disclosure and are not necessarily drawn to scale.

Although relative terms such as “up” and “down” are used in this specification to describe the relative relationship between one component illustrated in the drawings and another component, these terms are used in this specification for convenience only, for example, according to the illustrative direction depicted in the drawings. It can be understood that if the device illustrated in the drawings is inversed and turned upside down, the component described “above” would become the component “below”. When a structure is “on” other structure(s), it may mean that the structure is integrally formed on the other structure(s), or that the structure is “directly” arranged on the other structure(s), or that the structure is “indirectly” arranged on other structure(s) through another structure.

The terms “a”, “an”, “the”, and “said” are used to indicate the presence of one or more elements/components/etc.; the terms “comprising” and “including” are used to indicate open-ended inclusive means, and means that there may be additional elements/components/etc., in addition to the listed elements/components/etc; and the terms “first” and “second” are only used as markers, not to limit the number of objects.

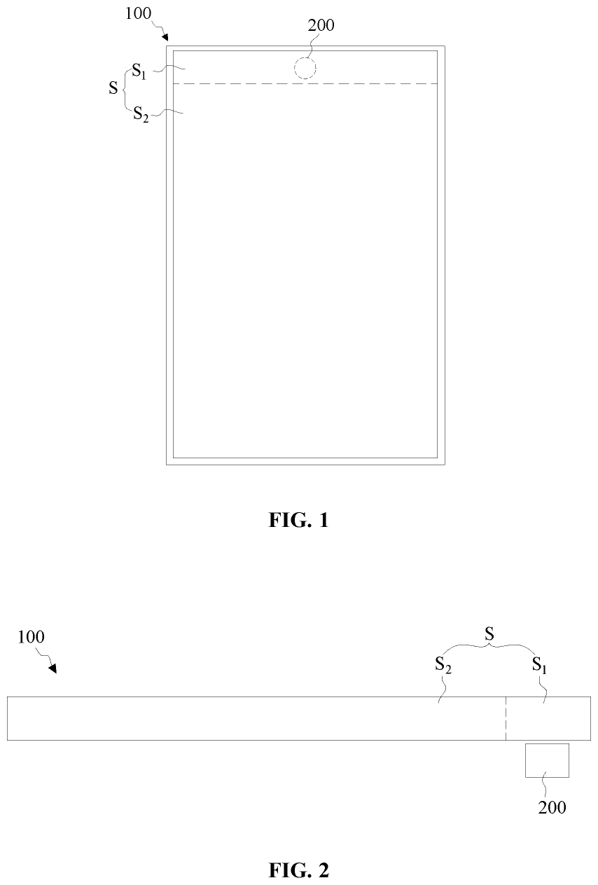

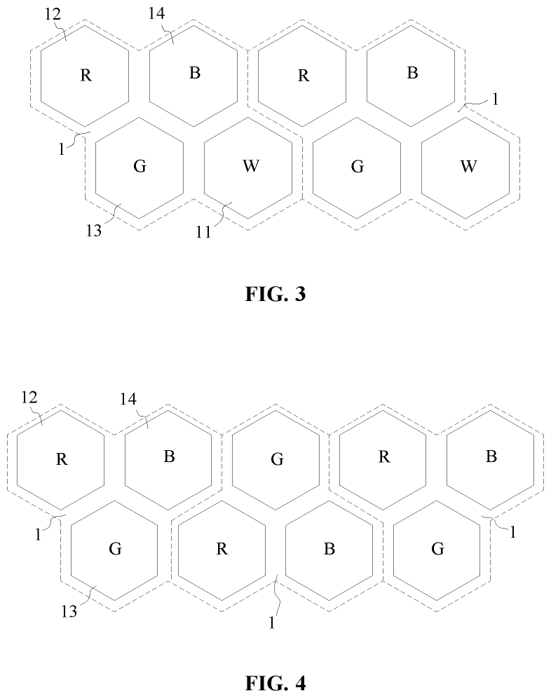

An embodiment of the present disclosure provides a display panel, which may be an OLED (Organic Light Emitting Diode) display panel. As shown in FIGS. 1 to 4, the display panel 100 of the present disclosure includes a display area S having a plurality of pixels 1, each of the which includes a plurality of sub-pixels.

The display area S is at least divided into a first area S₁ and a second area S₂, the pixel density of the first area S₁ is smaller than the pixel density of the second area S₂, and the number of sub-pixels in each of the pixels 1 of the first area S₁ is larger than the number of sub-pixels in each of the pixels 1 of the second area S₂.

In the display panel 100 according to the embodiment of the present disclosure, since the pixel density of the first area S₁ is smaller than that of the second area S₂, a large space may be reserved to transmit light, while providing space for the wiring, such that the transmittance of light in the first area S₁ is higher. When the pixels 1 in the first area S₁ are turned off, the camera module 200 may take an image through the first area S₁. When the pixels 1 in the first area S₁ are turned on, the image may be displayed normally, and the second area S₂ may always display an image normally, so that a hole or holes for mounting the camera module 200 on the display panel 100 may be avoided, and a full-screen display may be achieved. At the same time, the number of sub-pixels in each of the pixels 1 of the first area S₁ is greater than the number of sub-pixels in each of the pixels of the second area S₂, which may compensate for the lower luminous intensity caused by the decrease in the pixel density of the first area S₁, and reduce the difference in brightness between the first area S₁ and the second area S₂ when performing the full-screen display.

The display panel 100 according to the embodiment of the present disclosure is described in detail below.

As shown in FIGS. 3 and 4, respective pixels 1 in the first area S₁ and the second area S₂ are distributed in an array. The outline of each sub-pixel may be rectangular, rhombic, or other polygons. Optionally, it may also be other regular graphics, which are not listed here. The sub-pixels of the same pixel 1 may be arranged at intervals and distributed in a rectangular array, a parallelogram array, or other manners, which are not particularly limited herein.

It should be noted that, in the same pixel 1, the shapes and sizes of different sub-pixels may be the same or different.

The pixel density of the first area S₁ is smaller than the pixel density of the second area S₂. For example, the pixel density of the first area S₁ is larger than 200 PPI, and the pixel density of the second area S₂ is larger than 300 PPI, thereby preventing the first area S₁ from being too low to display the image properly. For example, the pixel density of the first area S₁ is 250 PPI, and the pixel density of the second area S₂ is larger than 300 PPI.

Each of the pixels 1 of the first area S₁ includes at least one white sub-pixel 11. The white sub-pixel 11 may compensate for the decrease in brightness caused by the low pixel density of the first area S₁. Examples are given as follow.

As shown in FIG. 3, the number of sub-pixels in each of the pixels of the first area S₁ is four, including a red sub-pixel 12, a green sub-pixel 13, a blue sub-pixel 14, and the above white sub-pixel 11.

As shown in FIG. 4, the number of sub-pixels in each of the pixels 1 of the second area S₂ is three, including a red sub-pixel 12, a green sub-pixel 13, and a blue sub-pixel 14, in which the white sub-pixel 11 is excluded.

It should be noted that the shapes of the sub-pixels having the same colour in the first area S₁ and the second area S₂ may be the same or different. The shape and distribution of the pixels shown in FIGS. 3 and 4 are merely exemplary illustrations.

In addition, by controlling the light emission intensity of the pixels 1 in the first area S₁ and the second area S₂, the brightness range of the first area S₁ and the second area S₂ may be the same, such that the difference in brightness may be reduced during full-screen display.

The display panel 100 of the present disclosure may include a substrate, and respective pixels 1 are disposed on a side of the substrate, and each of the pixels 1 may have an OLED structure. Specifically, the OLED structure may include a first electrode, a light-emitting layer, and a second electrode which are sequentially stacked in a direction away from the substrate. The light-emitting layer may include a hole injection layer, a hole transport layer, an organic electroluminescent layer, an electron transport layer, and an electron injection layer which are sequentially stacked in a direction away from the first electrode. The organic electroluminescent layer may be driven by the first electrode and the second electrode to emit light, and the specific light emitting principle is not described in detail here.

Both the first electrode and the second electrode of the white sub-pixel 11 include transparent materials, which may improve the light transmittance. When the white sub-pixel 11 does not emit light, it is transparent, which facilitates the camera module to capture images.

In an embodiment, the pixel 1 may be a top-emitting OLED. Specifically, in respective sub-pixels of each of pixels 1, except for the white sub-pixel 11, the remaining sub-pixels have their first electrodes provided with reflective structures, and their second electrodes provided with transparent structures, so that light may be emitted in a direction away from the substrate. The first electrode may include a metal such as aluminum, molybdenum, and the like, or an alloy, as long as it may reflect light. The second electrode may have a single-layer or multi-layer structure. For example, the second electrode may have a single-layer structure, and the material thereof is ITO (indium tin oxide). Alternatively, the second electrode may include two ITO film layers and a silver film layer provided therebetween.

In another embodiment, the pixel 1 may also be a bottom-emitting OLED. Specifically, in each of pixels 1, except for the white sub-pixel 11, the remaining sub-pixels have their first electrodes provided with transparent structures, and their second electrodes provided with reflective structures. For the transparent structures of the first electrodes, reference may be made to the above transparent structures of the second electrodes, and for the reflective structure of the second electrodes, reference may be made to the above reflective structures of the first electrodes, which will not be described in detail here.

It should be noted that the above-mentioned transparent structures of the first electrodes or second electrodes are not limited to being completely transparent, and may also include translucent, that is, as long as the transmittance is greater than 50%.

An embodiment of the present disclosure provides a display device including a display panel and a camera module 200, wherein:

the display panel may be the display panel 100 as described above, which is not described in detail here.

The camera module 200 is disposed on a backlight side of the display panel 100 to avoid blocking the light emitted by the display panel 100. For example, if the pixel 1 of the display panel 100 has a top-emitting OLED structure, the camera module 200 is located on a side of the first electrode away from the light-emitting layer; or, if the pixel 1 of the display panel 100 has a bottom-emitting OLED structure, the camera module 200 is located on a side of the second electrode away from the light-emitting layer.

The specific structure of the camera module 200 is not particularly limited here, and its orthographic projection on the display panel 100 is located within the first area S₁. That is, the camera module 200 directly faces the first area S₁, so that an image may be captured through the first area S₁ toward the light exit side of the display panel 100.

For the beneficial effects of the display device of the present disclosure, reference may be made to the beneficial effects of the display panel as described above, which are not described here again.

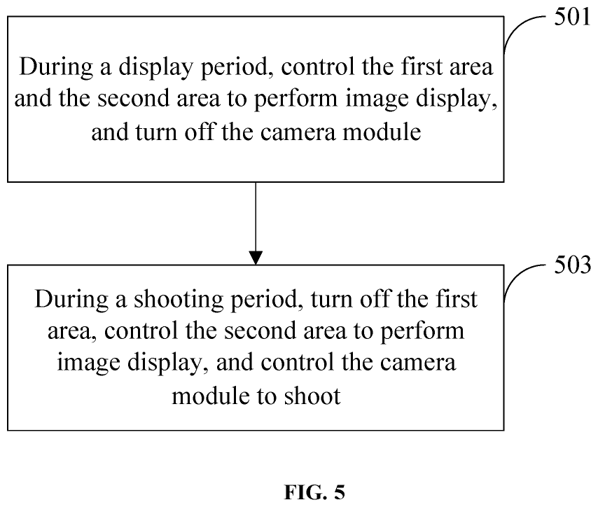

As shown in FIG. 5, an embodiment of the present disclosure also provides a method for driving the display device as described above, and its structure is not described in detail here. The driving method includes following steps.

In step 501, during a display period, controlling the first area and the second area to perform image display, and turning off the camera module; and

In step 503, during a shooting period, turning off the first area, controlling the second area to perform image display, and controlling the camera module to shoot.

According to the driving method of the present disclosure, full-screen display can be realized during the display period, that is, images may be displayed in both the first area S₁ and the second area S₂. When the camera module 200 is turned off, no image is captured. During the shooting period, only the first area S₁ may be turned off, and the second area S₂ may keep displaying images. At this time, the camera module 200 may capture images through the first area S₁. As a result, full-screen display and image capture may be achieved by controlling the first area S₁ and the camera module 200 without any opening holes in the display panel 100.

In addition, in order to improve the display effect, the driving method of the present disclosure may further include:

during the display period, controlling a brightness range of the first area to be the same as a brightness range of the second area.

Since the pixel density of the first area S₁ is smaller than the pixel density of the second area S₂, the brightness ranges of the first area S₁ and the second area S₂ can be substantially the same by controlling the light emission intensity of the pixels 1 in the first area S₁ and the second area S₂, thereby reducing the brightness difference.

It should be noted that although the respective steps of the method in the present disclosure are described in a specific order in the drawings, this does not require or imply that the steps must be performed in the specific order, or all steps shown must be performed to achieve desired results. Additionally or alternatively, certain steps may be omitted, multiple steps may be combined into one step for execution, and/or one step may be split into multiple steps for execution, and the like.

Those skilled in the art will readily contemplate other embodiments of the present disclosure after considering the specification and practicing the invention disclosed herein. This application is intended to cover any variations, uses, or adaptations of the present disclosure that conform to the general principles of the disclosure and include the common general knowledge or conventional technical means in the technical field not disclosed by the disclosure. It is intended that the specification and examples be considered as exemplary only, with a true scope and spirit of the disclosure being indicated by the appended claims.

What is claimed is:

1. A display panel, comprising a display area comprising a plurality of pixels, each of the pixels comprising a plurality of sub-pixels;
wherein the display area comprises at least a first area and a second area, and a pixel density of the first area is smaller than a pixel density of the second area, and a number of sub-pixels in each of the pixels of the first area is larger than the number of sub-pixels in each of the pixels of the second area; and
wherein at least part of pixels of the first area has an on state and an off state, the at least part of pixels is configured to perform image display under the on state and enable light to pass through the at least part of pixels under the off state.

2. The display panel according to claim 1, wherein each of the pixels of the first area comprises at least a white sub-pixel.

3. The display panel according to claim 2, wherein each of the sub-pixels comprises a first electrode, a light-emitting layer, and a second electrode which are sequentially stacked; and wherein both the first electrode and the second electrode of the white sub-pixel include transparent materials.

4. The display panel according to claim 2, wherein remaining sub-pixels, other than the white sub-pixel, have the first electrodes provided with reflective structures and the second electrodes provided with transparent structures.

5. The display panel according to claim 2, wherein remaining sub-pixels, other than the white sub-pixel, have the first electrodes provided with transparent structures and the second electrodes provided with reflective structures.

6. The display panel according to claim 2, wherein the number of sub-pixels in each of the pixels of the first area is four, including a red sub-pixel, a green sub-pixel, a blue sub-pixel and the white sub-pixel.

7. The display panel according to claim 2, wherein the number of sub-pixels in each of the pixels of the second area is three, including a red sub-pixel, a green sub-pixel and a blue sub-pixel.

8. The display panel according to claim 1, wherein the pixel density of the first area is larger than 200 PPI, and the pixel density of the second area is larger than 300 PPI.

9. A display device, comprising:
a display panel; and
a camera module disposed on a backlight side of the display panel and directly facing the first area,
wherein the display panel comprises a display area comprising a plurality of pixels, each of the pixels comprising a plurality of sub-pixels;
wherein the display area comprises at least a first area and a second area, and a pixel density of the first area is smaller than a pixel density of the second area, and a number of sub-pixels in each of the pixels of the first area is larger than the number of sub-pixels in each of the pixels of the second area; and
wherein at least part of pixels of the first area has an on state and an off state, the at least part of pixels is configured to perform image display under the on state and enable light to pass through the at least part of pixels under the off state.

10. The display device according to claim 9, wherein each of the pixels of the first area comprises at least a white sub-pixel.

11. The display device according to claim 10, wherein each of the sub-pixels comprises a first electrode, a light-emitting layer, and a second electrode which are sequentially stacked; and wherein both the first electrode and the second electrode of the white sub-pixel include transparent materials.

12. The display device according to claim 10, wherein remaining sub-pixels, other than the white sub-pixel, have the first electrodes provided with reflective structures and the second electrodes provided with transparent structures.

13. The display device according to claim 10, wherein remaining sub-pixels, other than the white sub-pixel, have the first electrodes provided with transparent structures and the second electrodes provided with reflective structures.

14. The display device according to claim 10, wherein the number of sub-pixels in each of the pixels of the first area is four, including a red sub-pixel, a green sub-pixel, a blue sub-pixel and the white sub-pixel.

15. The display device according to claim 10, wherein the number of sub-pixels in each of the pixels of the second area is three, including a red sub-pixel, a green sub-pixel and a blue sub-pixel.

16. The display device according to claim 9, wherein the pixel density of the first area is larger than 200 PPI, and the pixel density of the second area is larger than 300 PPI.

17. A method for driving a display device, the display device comprising a display panel; and a camera module disposed on a backlight side of the display panel and directly facing the first area, the display panel comprising a display area comprising a plurality of pixels, each of the pixels comprising a plurality of sub-pixels; the display area comprising at least a first area and a second area, a pixel density of the first area being smaller than a pixel density of the second area, and a number of sub-pixels in each of the pixels of the first area being larger than the number of sub-pixels in each of the pixels of the second area; at least part of pixels of the first area having an on state and an off state, and the at least part of pixels is configured to perform image display under the on state and enable light to pass through the at least part of pixels under the off state,
wherein the method comprises:
during a display period, controlling the first area and the second area to perform image display, and turning off the camera module; and
during a shooting period, turning off the at least part of pixels of the first area, controlling the second area to perform image display, and controlling the camera module to shoot.

18. The driving method according to claim 17, further comprising:
during the display period, controlling a brightness range of the first area to be same as a brightness range of the second area.
